(19) United States
(12) Patent Application Publication
(10) Pub. No.: US 2010/0212946 A1
(43) Pub. Date: Aug. 26, 2010

(54) WIRING BOARD AND METHOD FOR MANUFACTURING THE SAME

(75) Inventors: Keisuke SHIMIZU, Ogaki-shi (JP); Yoichiro KAWAMURA, Ogaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: IBIDEN CO., LTD, Ogaki-shi (JP)

(21) Appl. No.: 12/489,803

(22) Filed: Jun. 23, 2009

Related U.S. Application Data
(60) Provisional application No. 61/154,084, filed on Feb. 20, 2009.

(51) Int. Cl. H05K 1/16; H05K 3/30

(52) U.S. Cl. 174/260; 29/837; 174/261

(57) ABSTRACT

A wiring board including a substrate, an electronic component having an electrode and arranged inside the substrate, and a wiring layer formed over the substrate and connected to the electrode through a via hole. The electrode has a connection surface portion contacting the via hole, and the connection surface portion has a thickness which is made thinner than a thickness of the electrode surrounding the connection surface portion.

### CROSS-REFERENCE TO RELATED APPLICATIONS

The present application claims the benefits of priority to U.S. Application No. 61/154,084, filed Feb. 20, 2009. The contents of that application are incorporated herein by reference in their entirety.

### BACKGROUND OF THE INVENTION

1. Field of the Invention

The present invention is related to a wiring board with a built-in electronic component such as a resistor or capacitor, and a method for manufacturing such a wiring board.

2. Discussion of the Background

In Japanese Laid-Open Patent Publication 2006-32887, a wiring board with a built-in electronic component and its manufacturing method are described. A wiring board with a built-in electronic component is manufactured according to the manufacturing method by a worker who embeds an electronic component in a substrate and electrically connects a conductive pattern of the substrate and a terminal electrode (electrode pad) of the electronic component through a via hole. The contents of that publication are incorporated herein by reference in their entirety.

### SUMMARY OF THE INVENTION

A wiring board according to one aspect of the present invention has a wiring layer, an electronic component with an electrode, and a substrate. The electronic component is arranged inside the substrate, the electrode is connected to the wiring layer through a via hole, and the thickness of the electrode is reduced at the portion connected to the via hole.

“Arranged inside the substrate” includes cases in which the entire electronic component is completely embedded inside the substrate as well as cases in which only part of the electronic component is arranged in a hollow section formed in the substrate. In short, it is sufficient if at least part of an electronic component is arranged inside the substrate.

A method for manufacturing a wiring board according to another aspect of the present invention includes a step to arrange an electronic component with an electrode inside a substrate; a step to make part of the electrode thinner; a step to form a via hole to be connected to the portion of the electrode made thinner in the second step; and a step to form a wiring layer to be connected to the electronic component through the via hole formed in the third step.

Conducting the aforementioned steps is not limited to any order unless otherwise specified. For example, the second step may be conducted before the first step.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view showing a wiring board according to the First Embodiment of the present invention;

FIG. 2 is a cross-sectional view showing an electronic component to be built into a wiring board;

FIG. 3 is a view showing a positional relationship between terminal electrodes of the electronic component and via holes;

FIG. 4A is a magnified view of an electronic component to be built into a wiring board;

FIG. 4B is a magnified view showing part of FIG. (4A);

FIG. 5 is a view showing a sample to be used in simulations;

FIG. 6 is a table showing simulation results;

FIG. 7A is a graph showing simulation results;

FIG. 7B is a graph showing simulation results;

FIG. 8A is a view illustrating the principle of how the amount of Joule heat is decreased by partially reducing the thickness of the conductor inside a via hole;

FIG. 8B is a view illustrating the principle of how the amount of Joule heat is decreased by partially reducing the thickness of the conductor inside a via hole;

FIG. 9 is a flowchart showing the process of a method for manufacturing a wiring board according to the First Embodiment of the present invention;

FIG. 10A is a view illustrating a step to arrange an electronic component on a carrier;

FIG. 10B is a view illustrating a step to arrange an electronic component on the carrier;

FIG. 10C is a view illustrating a step to arrange an electronic component on the carrier;

FIG. 10D is a view illustrating a step to arrange an electronic component on the carrier;

FIG. 11A is a view illustrating a step to build (embed) an electronic component into a substrate;

FIG. 11B is a view illustrating a step to build an electronic component into the substrate;

FIG. 11C is a view illustrating a step to build an electronic component into the substrate;

FIG. 12A is a view illustrating a step to form a conductive pattern;

FIG. 12B is a view illustrating a step to form a conductive pattern;

FIG. 12C is a view illustrating a step to form a conductive pattern;

FIG. 13A is a cross-sectional view showing a wiring board according to the Second Embodiment of the present invention;

FIG. 13B is a magnified view of an electronic component to be built into the wiring board;

FIG. 14A is a view illustrating a step to prepare a substrate;

FIG. 14B is a view illustrating a step to form a space to build the electronic component into the substrate;

FIG. 14C is a view illustrating a step to mount the substrate on a carrier;

FIG. 14D is a view illustrating a step to mount the electronic component on the carrier;

FIG. 15A is a view illustrating a step to build (embed) an electronic component into a substrate;

FIG. 15B is a view illustrating a step to build an electronic component into the substrate;

FIG. 15C is a view illustrating a step to form a via hole;

FIG. 16 is a view showing another example of via holes;

FIG. 17A is a view showing an example of a wiring board using filled vias;

FIG. 17B is a view showing another example of a wiring board using filled vias;

FIG. 18A is a view showing another example of terminal electrodes of an electronic component and via holes;

FIG. 18B is a view showing yet another example of terminal electrodes of an electronic component and via holes;

FIG. 18C is a view showing yet another example of terminal electrodes of an electronic component and via holes;

FIG. 19A is a view showing yet another example of terminal electrodes of an electronic component and via holes;

FIG. 19B is a view showing yet another example of terminal electrodes of an electronic component and via holes; and

FIG. 19C is a view showing yet another example of terminal electrodes of an electronic component and via holes.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

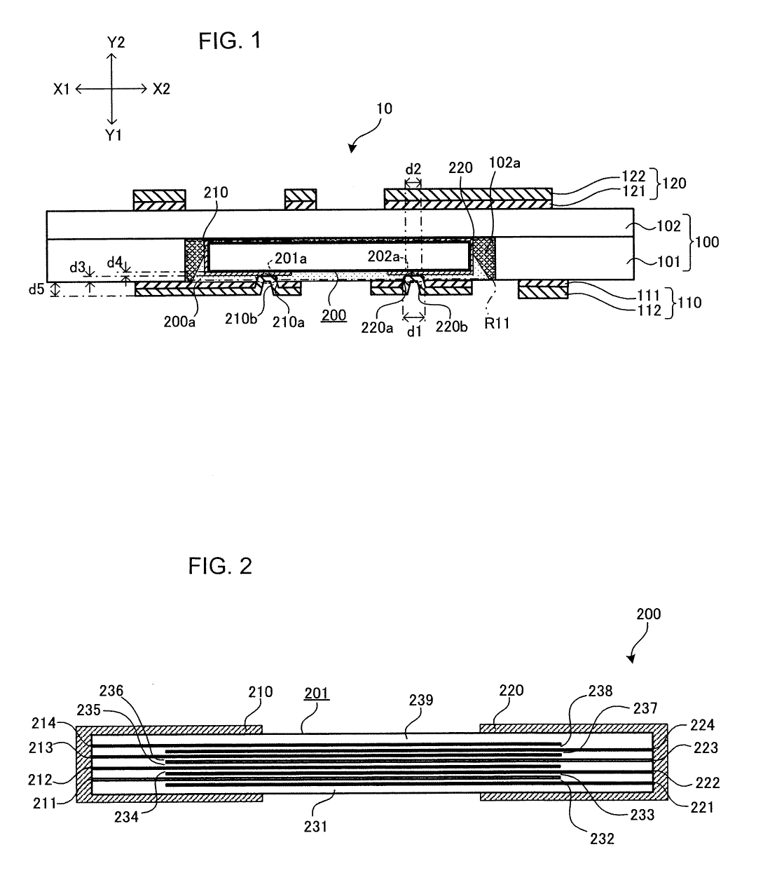

As shown in FIG. 1, wiring board (10) with a built-in electronic component according to the present embodiment has substrate (100), wiring layers (110, 120) as conductive patterns, and electronic component (200).

Substrate (100) is formed with square insulation layers (101, 102) made of cured prepreg, for example. The prepreg is preferred to contain reinforcing material such as glass fiber or aramid fiber impregnated with resin. The reinforcing material has a smaller coefficient of thermal expansion than the main material (prepreg). Insulation layer (101) has space (R11) configured to correspond to the outer shape of electronic component (200). Space (R11) will become a hollow section of substrate (100).

The configuration, material, etc., of substrate (100) may be modified according to usage requirements or the like. For example, as for prepreg, the following may also be used: base material such as glass fiber or aramid fiber impregnated with resin such as epoxy resin, bismaleimide triazine resin (BT resin), imide resin (polyimide), allyl polyphenylene ether resin (A-PPE resin) or the like. Also, instead of prepreg, thermosetting resins or thermoplastic resins in a liquid or film state may be used. As for thermosetting resins, for example, epoxy resin, imide resin (polyimide), BT resin, allyl polyphenylene ether resin, aramid resin or the like may be used. As for thermoplastic resins, for example, liquid crystal polymer (LCP), PEEK resin, PTFE resin (fluororesin) or the like may be used. Such resins are preferred to be selected according to requirements such as insulation, dielectric properties, heat resistance and mechanical features. In addition, such resins may contain curing agents, stabilizers, fillers or the like as additives. Alternatively, instead of prepreg, resin-coated copper foil (RCF) or the like may also be used.

On the surfaces (both surfaces) of substrate (100), wiring layers (110, 120) are formed. On the lower surface of substrate (100) (the side indicated by arrow (Y1)), wiring layer (110) is formed; and on the upper surface of substrate (100) (the side indicated by arrow (Y2)), wiring layer (120) is formed.

Wiring layer (110) has first wiring layer (111) and second wiring layer (112). Also, wiring layer (120) has first wiring layer (121) and second wiring layer (122). First wiring layers (111, 121) are made of, for example, copper foil. Second wiring layers (112, 122) are made of, for example, copper-plated film. Since wiring layers (110, 120) include first wiring layers (111, 121) (metal foil) and second wiring layers (112, 122) (plated metal film), adhesiveness will be enhanced between first wiring layers (111, 121) and insulation layers (101, 102), and they will seldom suffer delamination. The thickness of wiring layers (110, 120) is, for example, in the range of 20-30 μm. Here, the material, thickness and so forth of wiring layers (110, 120) may be modified according to usage requirements or the like.

In space (R11) of insulation layer (101), electronic component (200) is arranged, having substantially the same thickness as insulation layer (101). Insulative resin (102a) that has seeped (drained) from insulation layers (101, 102) along with adhesive (200a) to secure electronic component (200) is filled in the boundaries between electronic component (200) and substrate (100). Resin (102a) completely envelops electronic component (200). In doing so, electronic component (200) is protected by resin (102a) and is fixed to a predetermined position.

Adhesive (200a) is made from insulative material such as non-conductive liquid polymer (NCP). In insulative adhesive (200a), taper-shaped via holes (201a, 202a) are formed. Specifically, in first wiring layer (111) and adhesive (200a), tapered penetrating holes (210a, 220a) are formed to be connected to electronic component (200). Via holes (201a, 202a) are formed as part of penetrating holes (210a, 220a). In addition, on the wall and bottom surfaces of penetrating holes (210a, 220a), conductors (210b, 220b) that are contiguous to second wiring layer (112) are formed. Therefore, on the wall and bottom surfaces of via holes (201a, 202a) which are part of penetrating holes (210a, 220a), conductors (210b, 220b) are also formed respectively. Via hole (201a) and conductor (210b), and via hole (202a) and conductor (220b) each form a conformal via. Electronic component (200) and wiring layer (110) are electrically connected by means of such conformal vias. Lower-side (the side indicated by arrow (Y1)) opening diameter (d1) of penetrating holes (210a, 220a) is 60 μm, for example; and upper-side (the side indicated by arrow (Y2)) opening diameter (d2) of penetrating holes (210a, 220a) is 50 μm, for example. The configuration of penetrating holes (210a, 220a) is not limited to tapering, and any other configuration may be employed.

The diameter of via holes (201a, 202a) (for example, upper-side opening diameter (d2) of penetrating holes (210a, 220a)) is preferred to be set at 30-90 μm, more preferably at 50-60 μm. If the diameter of via hole (201a) or (202a) is too small, connection reliability will decrease. On the other hand, if the diameter of via hole (201a) or (202a) is too large, the required area for terminal electrodes (electrode pads) (210, 220) of electronic component (200) will increase, thus making it hard to highly integrate electronic component (200). However, if the diameter of via holes (201a, 202a) is set in the above range, wiring board (10) with a built-in electronic component may be manufactured with fewer such drawbacks.

Depth (d3) of via holes (201a, 202a) is preferred to be set at 1-10 μm, more preferably at 5 μm. If the depth of via holes (201a, 202a) is too shallow, making uniform holes becomes difficult. On the other hand, if the depth of via holes (201a, 202a) is too deep, forming such via holes takes a long time, and productivity will decrease. However, if the depth of via holes (201a, 202a) is in the above range, wiring board (10) with a built-in electronic component may be manufactured with fewer such drawbacks.

Electronic component (200) is a chip capacitor, for example. Specifically, as its cross-sectional structure shows in FIG. (2), electronic component (200) is formed with capacitor body (201) and U-shaped terminal electrodes (210, 220) (electrode pads). Capacitor body (201) is formed, for example, by alternately laminating multiple dielectric layers (231-239), made of ceramic, for example, with multiple conductive layers (211-214) and (221-224). Terminal electrodes (210, 220) are formed on both ends of capacitor body (201) respectively. Both ends of capacitor body (201), specifically, their lower surfaces, side surfaces and upper surfaces, are covered by terminal electrodes (210, 220) respectively. Since side surfaces of capacitor body (201) are covered by terminal electrodes (210, 220), efficiency in generating heat will increase. Meanwhile, the central section of capacitor body (201) is exposed. Electronic component (200) is not limited to a chip capacitor, and other passive components such as a chip resistor may also be used as electronic component (200).

As shown in FIG. 1, while being built into substrate (100), the lower surfaces of terminal electrodes (210, 220) of electronic component (200) are connected to wiring layer (110) by means of via hole (201a) and conductor (210b) and by via hole (202a) and conductor (220b) respectively. Here, second wiring layer (112) and conductors (210b, 220b) are made of copper-plated film, for example. Thus, reliability in the connected portions is high between electronic component (200) and wiring layer (110). Also, by forming plated metal film on the surface of terminal electrode (210) of electronic component (200), reliability in the connected portions will further increase between electronic component (200) and wiring layer (110).

Meanwhile, the central section of capacitor body (201) (FIG. 2) is coated with resin (102a). Since areas where relatively fragile ceramic portions are exposed (central section) in capacitor body (201) are coated with resin (102a), capacitor body (201) is protected by such resin (102a).

The thickness of terminal electrodes (210, 220) (especially thickness (d4) on the lower-surface side to which conductors (210b, 220b) are connected) is preferred to be set at 2-15 μm, more preferably at 5 μm. If terminal electrode (210) or (220) becomes thinner, their strength decreases accordingly. Therefore, if terminal electrode (210) or (220) is too thin, when forming via hole (201a) or (202a) by laser or the like, such a drilling process may not stop at terminal electrode (210) or (220), but may bore into terminal electrode (210) or (220). On the other hand, if terminal electrode (210) or (220) is too thick, there may be a concern that cracks will occur in electric component (200). Besides, since wiring board (10) with a built-in electronic component becomes larger, drawbacks such as mounting space or the like will arise. However, if the thickness of terminal electrodes (210, 220) is set in the above range, wiring board (10) with a built-in electronic component may be formed with fewer such drawbacks in terms of strength and cracking.

Thickness (d5) of wiring layer (110) is preferred to be set at 15-40 μm, preferably at 30 μm. If wiring layer (110) is too thin, electric resistance increases, which is not preferable for energy efficiency or the like. On the other hand, if wiring layer (110) is too thick, it takes longer to form such layers, which is not preferable for manufacturing efficiency. Especially, when wiring layer (110) is formed by plating, drawbacks such as difficulty in depositing uniform plated metal film or difficulty in forming and removing plating resist may arise. However, if the thickness of wiring layer (110) is in the above range, wiring board (10) with a built-in electronic component may be manufactured with fewer such drawbacks in terms of energy efficiency and manufacturing efficiency.

In addition, the ratio between the thickness (especially lower-surface side thickness (d4)) of terminal electrode (210) or (220) and thickness (d5) of wiring layer (110) is preferred to be set so that the thickness of terminal electrode (210) or (220) is less than the thickness of wiring layer (110). Especially, the thickness of terminal electrode (210) or (220) is preferred to be set at half (½) or smaller than half the thickness of wiring layer (110). If the ratio is set as such, by making terminal electrode (210) or (220) thinner, cracking or the like may be suppressed from occurring in electronic component (200). Moreover, if the thickness of wiring layer (110) is thicker to compensate for the reduced thickness of terminal electrode (210) or (220), a high level of heat dissipation may be maintained.

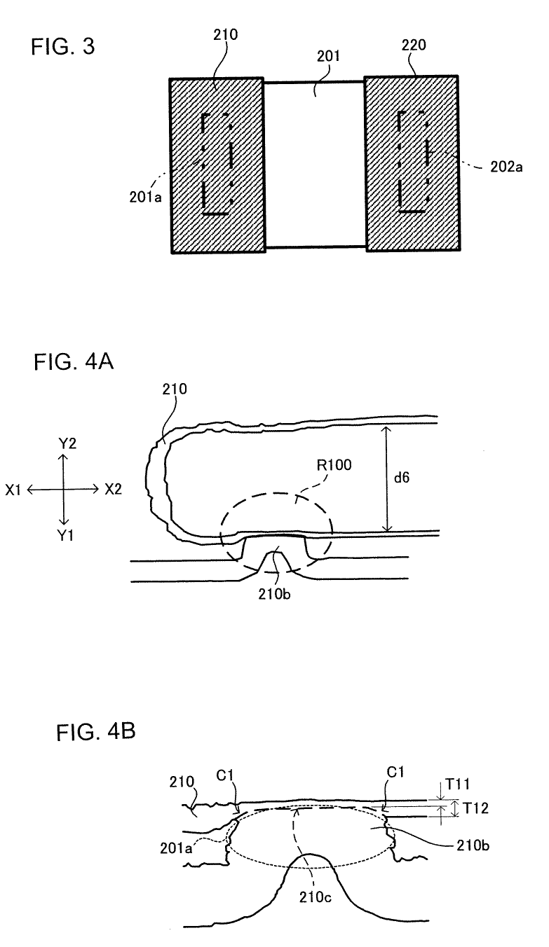

Via holes (201a, 202a) are each arranged, for example, in the center of terminal electrode (210, 220) of electronic component (200) as shown in FIG. 3.

FIG. 4A is a magnified view showing part of electronic component (200). Electronic component (200) is configured to be 1 mm by 1 mm square and thickness (d6) of electronic component (200) is set at 100-150 μm, for example. The surfaces of terminal electrodes (210, 220) are roughened. Via holes (201a, 202a) are connected to the lower surface (the side indicated by arrow (Y1)) of electronic component (200).

Moreover, as a magnified view of region (R100) in FIG. 4A shows in FIG. 4B, at connection surface (210c) of terminal electrode (210) and conductor (210b), thickness (T11) of terminal electrode (210) is selectively made thinner at that portion. Namely, thickness (T11) is made thinner than surrounding thickness (T12) of terminal electrode (210). Thickness (T11) is 2 μm, for example, and thickness (T12) is 5 μm, for example. Accordingly, a concave portion of terminal electrode (210) is formed in connection surface (210c) (see double-dotted lines in FIG. 3).

With such a structure, since thickness (T11) of terminal electrode (210) is partially made thinner, the front ends (connection surfaces (210c)) of via holes (201a, 202a) are set closer to the section (central section) of electronic component (200) where heat tends to be generated. Thus, heat-dissipation efficiency will increase.

Also, boundary portions (C1) between the bottom and wall surfaces of via holes (201a, 202a) are rounded. Thus, the degree of bend from the bottom toward the wall surface becomes gradual, and plating performance improves when forming conductors (210b, 220b) (plated metal film).

Here, for the sake of convenience, only the side of terminal electrode (210) is shown in the drawing, and the structure surrounding it has been described. However, the same applies to the side of terminal electrode (220).

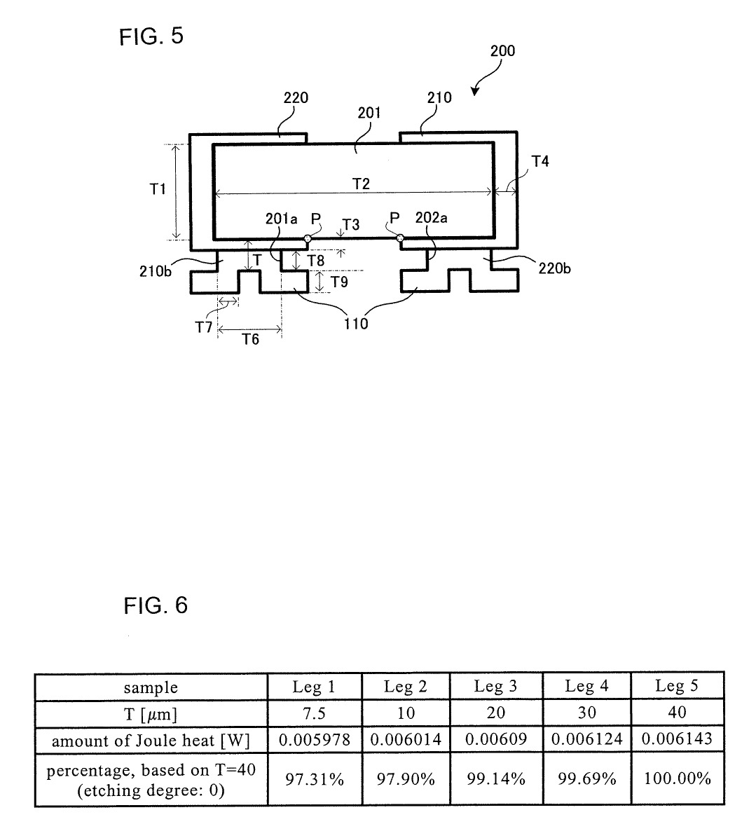

To further enhance heat-dissipation efficiency and electrical characteristics, it is effective if the thickness of conductors (210b, 220b) inside via holes (201a, 202a) is made partially thinner by etching or the like. Regarding such treatment, the simulation results for wiring board (10) with a built-in electronic component are described with reference to FIGS. 5-8B.

The simulations were carried out on samples Leg 1-Leg 5. The dimensions of such samples Leg 1-Leg 5 shown in FIG. 5 were as follows: thickness (T1) of capacitor body (201): 150 μm; width (T2) of capacitor body (201): 1,000 μm; vertical thickness (T3) of terminal electrodes (210, 220): 10 μm each; side thickness (T4) of terminal electrodes (210, 220): 30 μm each; connection width (T6) of conductors (210b, 220b): 70 μm each; width (T7) of the portions where conductor (210b) or (220b) and wiring layer (110) are laminated: 30 μm each; depth (T8) of via holes (201a, 202a): 30 μm each; and thickness (T9) of wiring layer (110): 30 μm.

Thickness (T) at each central portion of conductors (210b, 220b) registered 7.5 μm in sample Leg 1; 10 μm in sample Leg 2; 20 μm in sample Leg 3; 30 μm in sample Leg 4; and 40 μm in sample Leg 5. Electric resistance (Ω·m) was 70e⁻⁸ in capacitor body (201) and 1.68e⁻⁸ in copper. Thermal conductivity (W/m·K) was 25.1 in capacitor body (201) and 398 in copper.

The person who took measurements in simulations reproduced the constant state of wiring board (10) with a built-in electronic component based on a two-dimensional steady-state analysis, and calculated the amount of Joule heat generated by electric current. As the simulation conditions, interlayer material was assumed to be located around electronic component (200), thermal conductivity was set at 0.3 W/m²·K and electric current was set at 0.001 A. Also selected was measuring point (P) (FIG. 5), a spot where the heating value is large and damage actually tends to occur, namely, a spot where the heating value was found the largest as the result of simulations. Specifically, the lower step portion between capacitor body (201) and terminal electrode (210) or (220) (especially the spot where an electrode touches capacitor body (201)) was set as measuring point (P).

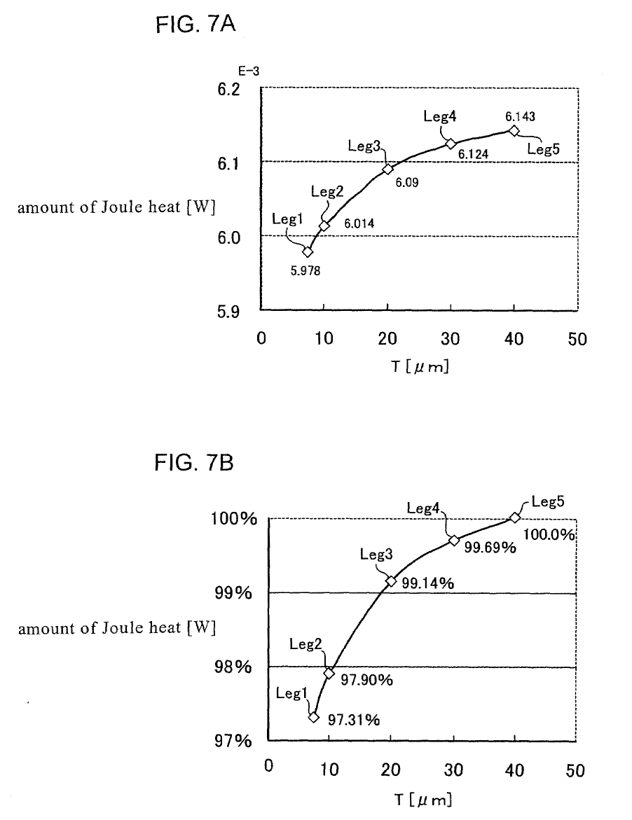

The simulation results of samples Leg 1-Leg 5 were shown in the table in FIG. 6 and graphs in FIGS. 7A and 7B. As shown in each table and graph, the greater the thickness (T) becomes, the more the heating value increases. For example, if thickness (T) was reduced from 40 μm (sample Leg 5) to 7.5 μm (sample Leg 1), the heating value decreased by approximately 3 percent.

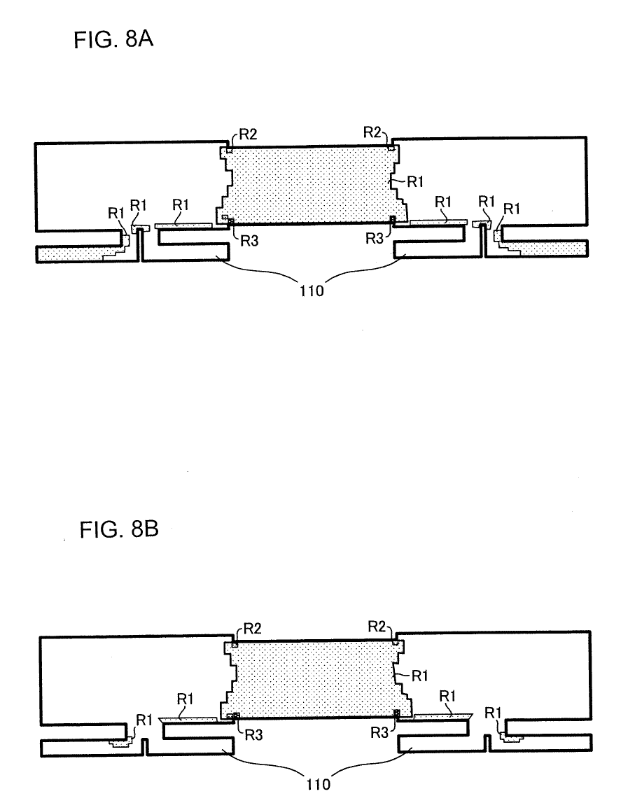

Also, the distribution of Joule heat during that time was measured in samples Leg 1 and Leg 2 with smaller thicknesses (T), and samples Leg 3-Leg 5 with larger thicknesses (T). The results were shown in FIGS. 8A and 8B. As shown in each view, in all samples with smaller thickness (T) as well as samples with larger thickness (T), the following were observed: region (R1) with lower heating value in the central section of capacitor body (201) (specifically, between terminal electrodes (210) and (220)); (R2) with medium heating value at the upper step portion between capacitor body (201) and terminal electrode (210) or (220); and (R3) with higher heating value in the lower step portion between capacitor body (201) and terminal electrode (210) or (220). Moreover, in samples with smaller thickness (T), namely samples Leg 1 and Leg 2, heat in capacitor body (201) was observed to be dissipated from wiring layer (110) as shown in FIG. 8A. Regarding the finding that heat value is less in samples with smaller thickness (T) than samples with larger thickness (T) (see FIGS. 7A and 7B), the inventors think that the finding stems from heat dissipation at wiring layer (110).

Also, in another simulation, the following results were obtained: namely, when thickness (T) was smaller, positive charge (+) and negative charge (−) were mixed in the current density of conductors (210b, 220b), whereas positive charge (+) dominated in the current density of conductors (210b, 220b) when thickness (T) was larger. According to the assumptions made by the inventors, when currents flow only in one direction as in wiring board (10) with a built-in electronic component having smaller thickness (T), metal ions of conductors (210b, 220b) may tend to be unevenly distributed, thus causing electromigration more frequently. Thus, if thickness (T) is set smaller, namely, part of the thickness of conductors (210b, 220b) is made thinner (for example, at their central sections), currents flowing into capacitor body (201) will be suppressed, and thus negative charge (−) may be mixed in the current density. As a result, electromigration is thought to be suppressed.

As such, by thinning part of the thickness of conductors (210b, 220b), heat may dissipate more efficiently and electrical characteristics may be improved.

On the other hand, thickness (T12) of terminal electrode (210) is sufficiently thick in areas except where the electrode touches via holes (201a, 202a). Thus, even if electronic component (200) is a chip capacitor which is fragile and may easily break, such electronic component (200) may be protected more securely. Namely, by simplifying the structure of wiring board (10) with a built-in electronic component, degradation of its performance by thermal stress may be suppressed.

Moreover, connection surface (210c) between terminal electrode (210) and conductor (210b) is roughened. Thus, adhesiveness is enhanced between terminal electrode (210) and conductor (210b).

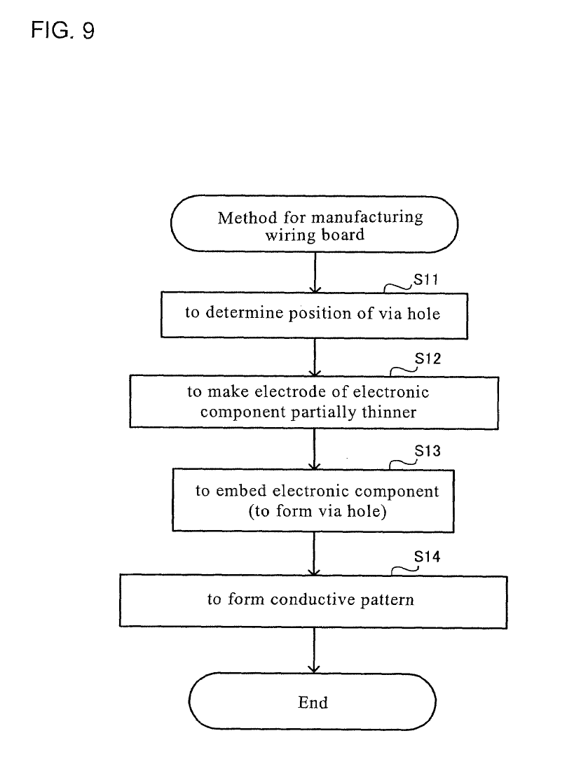

When manufacturing wiring board (10) with a built-in electronic component, for example, a worker carries out a series of processes shown in FIG. 9.

In step (S11), the worker determines where to form via holes (201a, 202a) based on the result of stress analysis or the like.

In step (S12), the worker makes thickness (T11) of terminal electrode (210) at connection surface (210c) between terminal electrode (210) and conductor (210b) thinner than thickness (T12) of terminal electrode (210) surrounding the connection surface (see FIG. 4B). Such a process to make a thinner film may be conducted by etching, by a laser or the like.

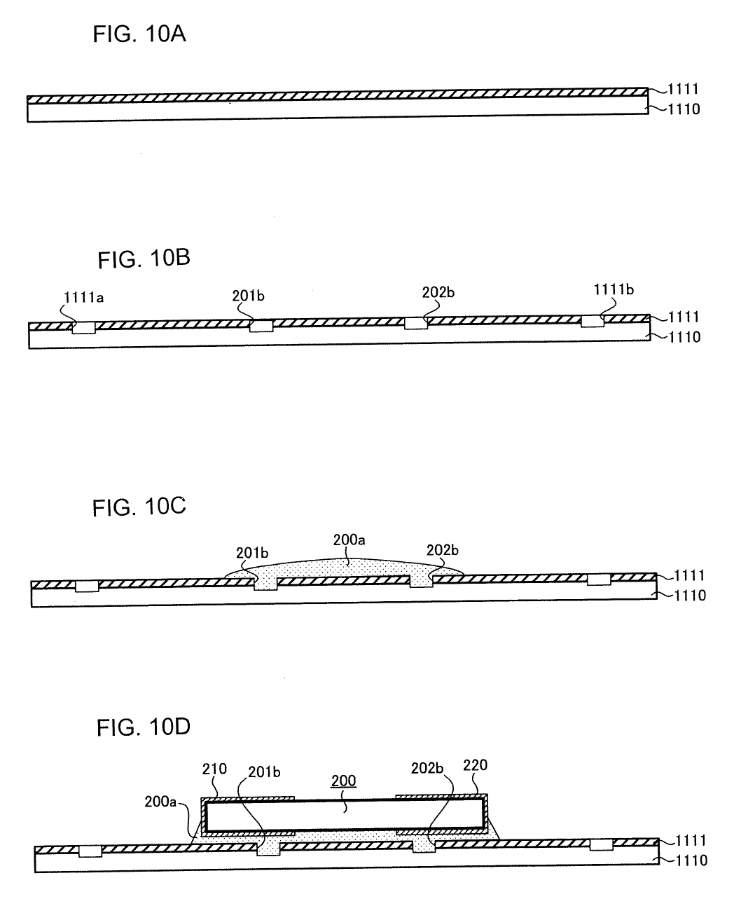

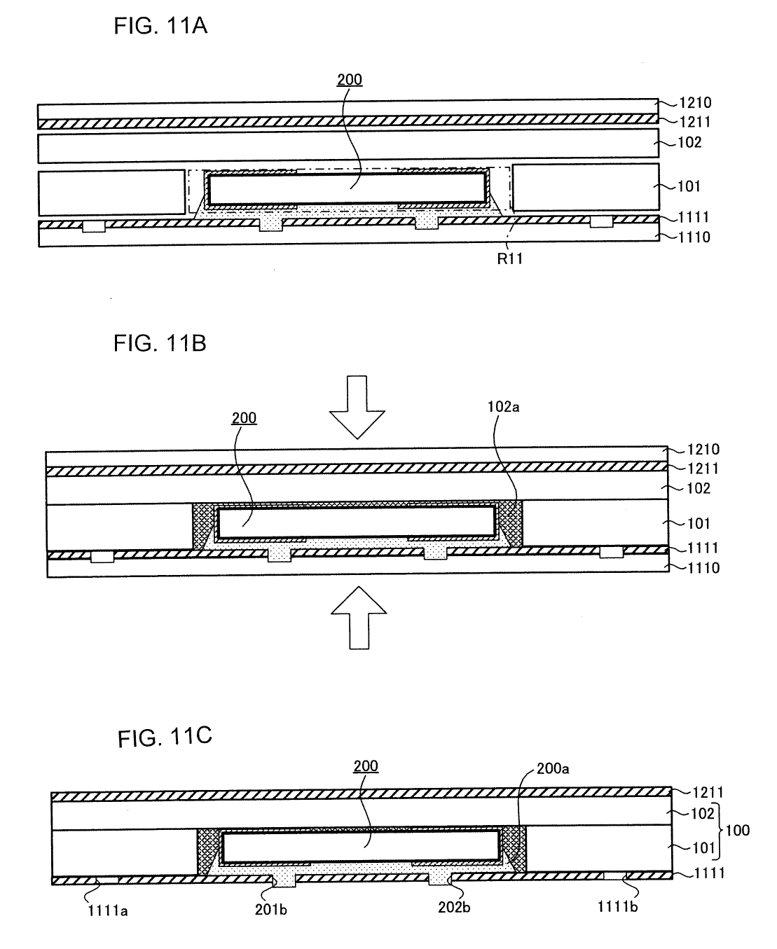

Instep (S13), the worker embeds electronic component (200) through the process shown in FIGS. 10A-10D and FIGS. 11A-11C, for example.

Specifically, the worker prepares carrier (1110) having conductive film (1111) on one side as shown in FIG. 10A, for example. Carrier (1110) and conductive film (1111) are both made of copper, for example. However, carrier (1110) is thicker than conductive film (1111).

The worker makes holes using a UV laser or the like to penetrate only conductive film (1111) as shown in FIG. 10B. Accordingly, opening portions (201b, 202b, 1111a, 1111b) are formed. Opening portions (201b, 202b) are formed in the spots for via holes (201a, 202a) determined at step (S11) (position-determination step). Opening portions (1111a, 1111b) are used as alignment targets.

As shown in FIG. 10C, the worker applies adhesive (200a) in the central area of carrier (1110) and conductive film (1111) including at least opening portions (201b, 202b) using NCP coating, for example. By doing so, adhesive (200a) is filled in opening portions (201b, 202b).

The worker mounts electronic component (200) on opening portions (201b, 202b) as shown in FIG. 10D.

Specifically, electronic component (200) with terminal electrodes (210, 220) is prepared. The surfaces of terminal electrodes (210, 220) are roughened. After electronic component (200) is mounted on adhesive (200a), electronic component (200) is fixed to that position by adding pressure and heat, for example. During that time, electronic component (200) is pressed down so that the thickness of adhesive (200a) will become uniform under electronic component (200) and voids will not remain inside. Such a process is important to secure connection reliability of via holes (201a, 202a) in the later process. The surfaces of terminal electrodes (210, 220) are usually roughened when those electrodes are formed. However, according to requirements, the surfaces may be roughened using chemicals or the like after the electrodes are formed.

As shown in FIG. 11A, for example, on carrier (1110) and conductive film (1111) made of copper, for example, insulation layer (101) made of prepreg, for example, is formed to be set horizontal to electronic component (200); and further on the top, insulation layer (102) made of prepreg, for example, and conductive film (1211) and carrier (1210) made of copper, for example, are each arranged. Electronic component (200) is arranged in space (R11) positioned in the center of insulation layer (101).

The worker conducts pressure-pressing (for example, thermal pressing) as shown in FIG. 11B, for example. In doing so, resin (102a) is squeezed out from insulation layers (101, 102). Namely, by such pressing, resin (102a) seeps from (drains from) each prepreg that forms insulation layers (101, 102) and is filled between electronic component (200) and insulation layer (101) (boundary portions). After that, insulation layers (101, 102) are cured through a thermal process, for example.

The worker removes carriers (1110, 1210) as shown in FIG. 11C, for example. In doing so, conductive films (1111, 1211) and adhesive (200a) filled in opening portions (201b, 202b) are exposed.

Accordingly, electronic component (200) is embedded in substrate (100). Electronic component (200) is arranged in the hollow section (space (R11)) of substrate (100).

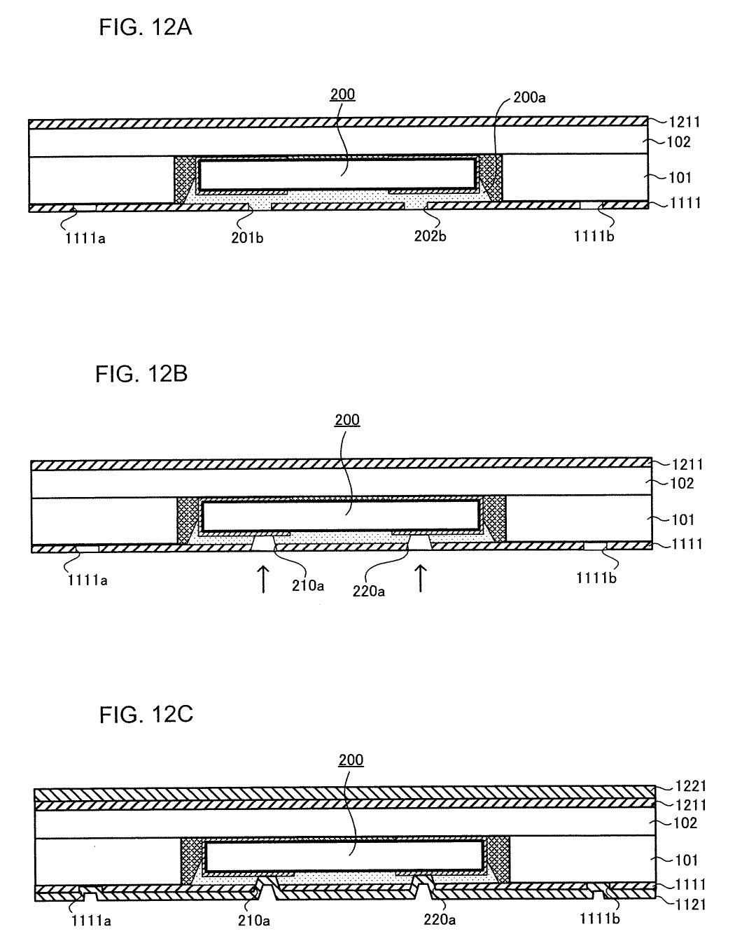

At step (S14) of FIG. 9, the worker forms conductive patterns by the steps shown in FIGS. 12A-12C, for example.

More specifically, the worker conducts CO₂ laser cleaning and desmearing as shown in FIG. 12A, for example. In doing so, adhesive (200a) on the surface of conductive film (1111) is removed. However, the step for such cleaning and desmearing is not always required, and thus may be omitted.

As shown in FIG. 12B, the worker forms penetrating holes (210a, 220a) that reach electronic component (200) in conductive film (1111) and adhesive (200a) using a laser or the like. In doing so, via holes (201a, 202a) are formed as parts of penetrating holes (210a, 220a).

As shown in FIG. 12C, for example, the worker performs PN plating (such as chemical copper plating and copper electroplating) to form conductive films (1121, 1221) (copper-plated films) on the surfaces of conductive films (1111, 1211) including penetrating holes (210a, 220a) and opening portions (1111a, 1111b).

The worker conducts a predetermined lithography process (preliminary treatment, lamination, exposure and development, etching, removal of the film, inner-layer inspection and so forth) to pattern conductive films (1111, 1121, 1211, 1221) in such a configuration as shown in FIG. 1. In doing so, first wiring layer (111) and second wiring layer (112) (wiring layer 110) along with first wiring layer (121) and second wiring layer (122) (wiring layer 120) are formed. Instead of using such a subtractive method to form conductive patterns, another method, a so-called semi-additive (SAP) method, may also be used; namely, plating resist is formed on insulation layers (101, 102), and wiring layers (110, 120) are formed by pattern plating (such as chemical copper plating and copper electroplating). Alternatively, through-holes may also be formed by forming openings that penetrate insulation layers (101, 102) prior to forming conductive patterns, and then performing plating in such openings while forming wiring layers (110, 120).

Also, the worker forms electrodes by chemical gold plating or the like according to requirements, and conducts external processing, warping correction, conductivity inspection, exterior inspection and final inspection. In doing so, wiring board (10) with a built-in electronic component is completed as shown in FIG. 1.

Wiring board (10) with a built-in electronic component according to the present embodiment shows excellent connection reliability in via holes (201a, 202a) in a heat cycle, for example, between −25° C. and 140° C. As a result, via holes (201a, 202a) with smaller diameters may be achieved.

Also, since thickness (T12) of terminal electrode (210) is sufficiently thick in areas except where the terminal electrode comes in contact with via holes (201a, 202a), the strength of electronic component (200) is maintained at a high level. Accordingly, even if electronic component (200) is thin, reliability when built into a substrate is enhanced.

Using the manufacturing method of the present embodiment, wiring board (10) with a built-in electronic component featuring the above structure may be manufactured simply and easily.

### Second Embodiment

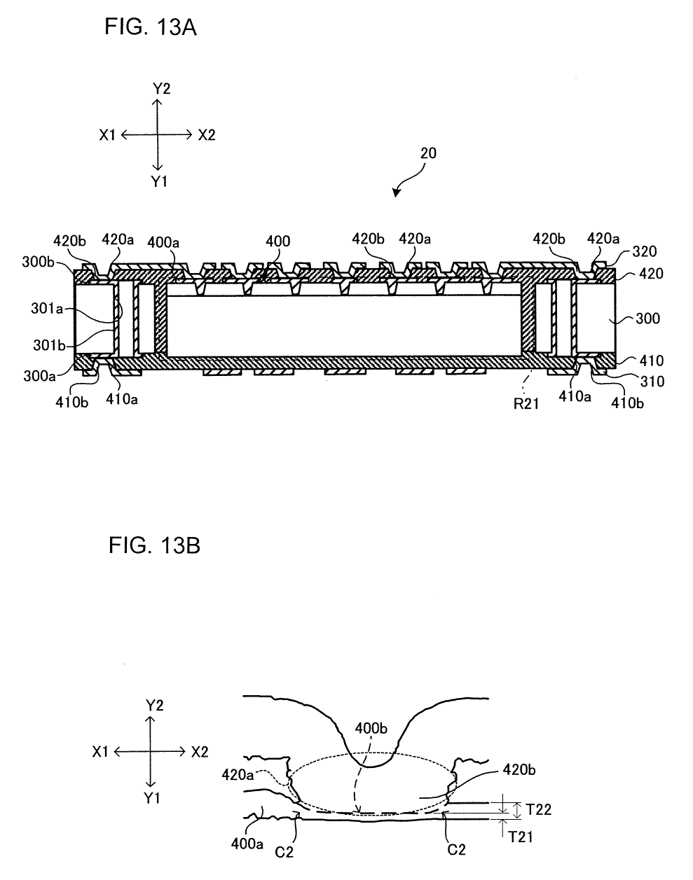

As shown in FIG. 13A, wiring board (20) with a built-in electronic component of the present embodiment has substrate (300), wiring layers (310, 320) as conductive patterns, and electronic component (400). Electronic component (400) is built into wiring board (20) as its built-in electronic component. Electronic component (400) is an IC chip with predetermined integrated circuits. Electronic component (400) has multiple terminal electrodes (400a) (electrode pads) on one surface. The surfaces of terminal electrodes (400a) are roughened. An IC chip referred to here includes a so-called wafer-level CSP, which is formed by forming protective films, terminals, etc., on a wafer, further rewiring and so forth, then by separating the wafers into units. Also, electronic component (400) may have terminal electrodes (400a) on both surfaces.

Substrate (300) is made from, for example, epoxy resin. Epoxy resin is preferred to contain reinforcing material such as glass fiber or aramid fiber impregnated with resin. The reinforcing material has a smaller thermal expansion coefficient than primary material (epoxy resin) has. The thickness of substrate (300) is, for example, 0.1 mm. However, the configuration, thickness, material and so forth of substrate (300) may be modified according to usage requirements or the like.

Substrate (300) has through-holes (301a). On the inner walls of through-holes (301a), conductive film (301b) is formed. In addition, substrate (300) has space (R21) whose configuration corresponds to the external shape of electronic component (400).

On the surfaces (both surfaces) of substrate (300), wiring layers (300a, 300b) are formed respectively. Wiring layer (300a) and wiring layer (300b) are electrically connected to each other by means of conductive film (301b) formed in through-holes (301a).

On the lower surface of substrate (300) (the side indicated by arrow (Y1)), insulation layer (410) and wiring layer (310) are laminated in that order. Also, on the upper surface of substrate (300) (the side indicated by arrow (Y2)), insulation layer (420) and wiring layer (320) are laminated in that order. Insulation layers (410, 420) are made of, for example, cured prepreg. Also, wiring layers (310, 320) are made of, for example, copper-plated film.

Electronic component (400) is arranged in space (R21). In the boundary portions between electronic component (400) and substrate (300), insulation layer (420) is filled.

Insulation layer (410) is formed to cover the lower surface of electronic component (400) and wiring layer (300a). Here, at the predetermined spots, via holes (410a) in a tapered shape are formed to be connected to wiring layer (300a). On the wall and bottom surfaces of via holes (410a), conductor (410b) is formed; via holes (410a) and conductor (410b) form conformal vias. Then, by means of such conformal vias, wiring layer (300a) and wiring layer (310) are electrically connected.

Meanwhile, insulation layer (420) is formed to cover the upper surface of electronic component (400), wiring layer (300b) and terminal electrodes (400a). Here, at predetermined spots, via holes (420a) are formed in a tapered shape to be connected to wiring layer (300b) and terminal electrodes (400a). On the wall and bottom surfaces of via holes (420a), conductor (420b) is formed; via holes (420a) and conductor (420b) form conformal vias. Then, wiring layer (300b) and terminal electrodes (400a) are electrically connected to wiring layer (320) by means of such conformal vias. Here, wiring layer (320) and conductor (420b) are made of, for example, copper-plated film. Therefore, reliability is high in the connection areas between electronic component (400) and wiring layer (320).

Electronic component (400) is completely enveloped by insulation layers (410, 420). In doing so, electronic component (400) is protected by insulation layers (410, 420) while being fixed to a predetermined position.

In electronic component (400), as shown in FIG. 13B (corresponding to FIG. 4B), for example, thickness (T21) of terminal electrode (400a) is also selectively made thinner in connection surface (400b) between terminal electrode (400a) and conductor (420b). Namely, thickness (T21) is made thinner than thickness (T22) of terminal electrode (400a) surrounding the connection surface. Accordingly, a concave portion is formed in terminal electrode (400a) where the electrode comes in contact with the conductor.

Also, boundary portions (C2) between the bottom and wall surfaces of via holes (420a) are rounded. Thus, the degree of bend from the bottom toward the wall surface becomes gradual, and plating performance improves when forming conductor (420b) (plated metal film).

Here, for the sake of convenience, only one terminal electrode (400a) is shown in the drawing, and the structure surrounding it has been described. However, the rest of terminal electrodes (400a) are the same.

Wiring board (20) with a built-in electronic component may also be manufactured by a worker, for example, who carries out a series of processes shown previously in FIG. 9. Specifically, in step (S11), the worker determines where to form via hole (420a) (especially, via hole (420a) which will be connected to terminal electrode (400a)), based on the result of stress analysis or the like, for example.

In step (S12), the worker makes thickness (T21) of terminal electrode (400a) at connection surface (400b) between terminal electrode (400a) and conductor (420b) thinner than thickness (T22) of terminal electrode (400a) surrounding the connection surface (see FIG. 13B). Such a process to make a thinner film may be conducted by etching, by a laser or the like.

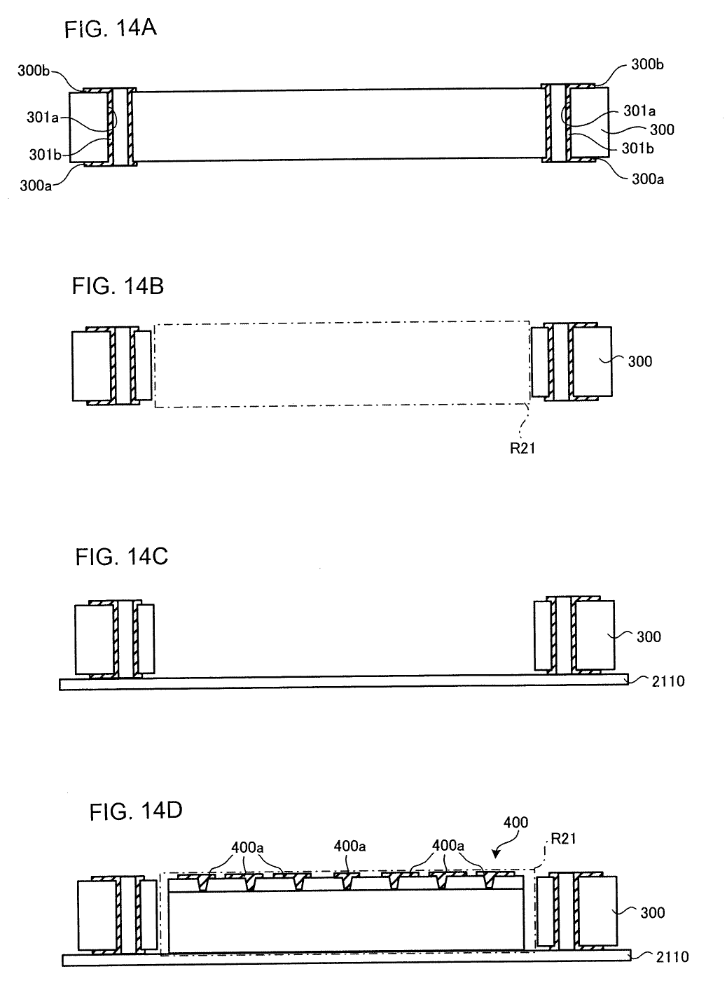

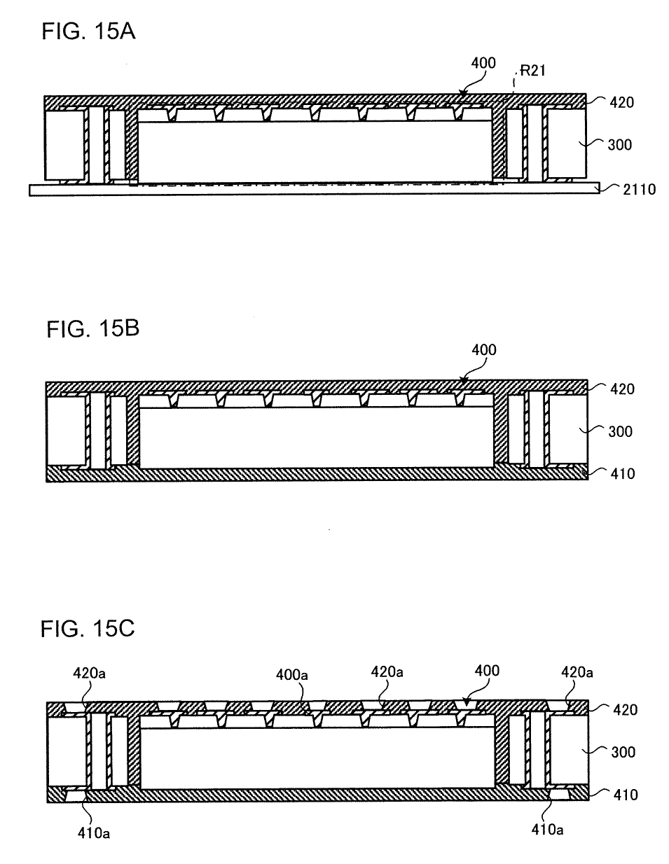

In step (S13), the worker embeds electronic component (400) through the process shown in FIGS. 14A-14D and FIGS. 15A-15C, for example.

More specifically, the worker prepares substrate (300) having through-holes (301a) and conductive film (301b) along with wiring layers (300a, 300b) as shown in FIG. 14A, for example. Substrate (300) corresponds to a core of wiring board (20) with a built-in electronic component.

The worker forms space (R21) in substrate (300) by making a hollow section using a laser or the like as shown in FIG. 14B, for example.

As shown in FIG. 14C, for example, the worker arranges carrier (2110) made of polyethylene terephthalate (PET), for example, on one side of substrate (300). Carrier (2110) is adhered to substrate (300) by lamination, for example.

As shown in FIG. 14D, the worker mounts at room temperature, for example, electronic component (400) on carrier (2110) (specifically on space (R21)) in such a way that terminal electrodes (400a) of electronic component (400) face upward (the side opposite carrier (2110)). The surfaces of terminal electrodes (400a) are roughened. Such roughened surfaces of terminal electrodes (400a) are usually formed when the electrodes are formed. However, if necessary, the surfaces may be roughened using a chemical or the like after the electrodes are formed.

As shown in FIG. 15A, the worker forms insulation layer (420) to coat electronic component (400) and substrate (300) using a vacuum laminator, for example. In doing so, terminal electrodes (400a) are coated with insulation layer (420). Furthermore, insulation layer (420) is melted by heat and filled in space (R21). Accordingly, electronic component (400) is fixed to a predetermined position.

The worker peels and removes carrier (2110) from the lower surface (the surface opposite insulation layer (420)) of substrate (300). Then, as shown in FIG. 15B, for example, insulation layer (410) is formed on the lower surface of substrate (300). In doing so, electronic component (400) is embedded in substrate (300).

As shown in FIG. 15C, the worker forms via holes (410a, 420a) in insulation layers (410, 420) using a laser or the like.

In step (S14) of FIG. 9, the worker forms conductive patterns, namely, wiring layers (310, 320) on electronic component (400) by a semi-additive method, for example. Specifically, both surfaces of electronic component (400) are covered with patterned plating resist, and electrolytic plating is performed selectively on the areas not covered by such resist. Instead of a semi-additive method, a subtractive method may also be used to form wiring layers (310, 320).

The worker forms electrodes by chemical gold plating or the like according to requirements, and carries out external processing, warping correction, conductivity inspection, exterior inspection and final inspection. Accordingly, wiring board (20) with a built-in electronic component is complete as shown previously in FIG. 13A.

The same effects described in the First Embodiment may be achieved in wiring board (20) with a built-in electronic component and its manufacturing method according to the present embodiment.

So far, the wiring boards and manufacturing methods according to the embodiments of the present invention have been described. However, the present invention is not limited to the above embodiments. For example, the present invention may be carried out by modifying it as follows.

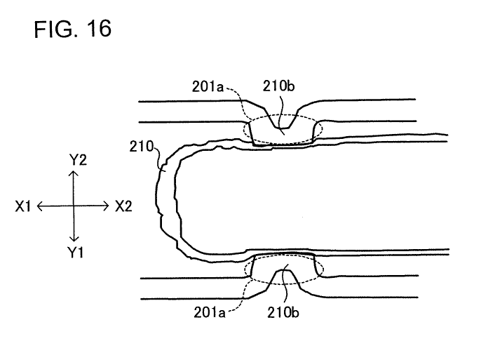

For example, as shown in FIG. 16 (only the side of via hole (201a) is shown for the sake of convenience), via holes (201a, 202a) may be formed on both surfaces of electronic component (200). The same applies to electronic component (400).

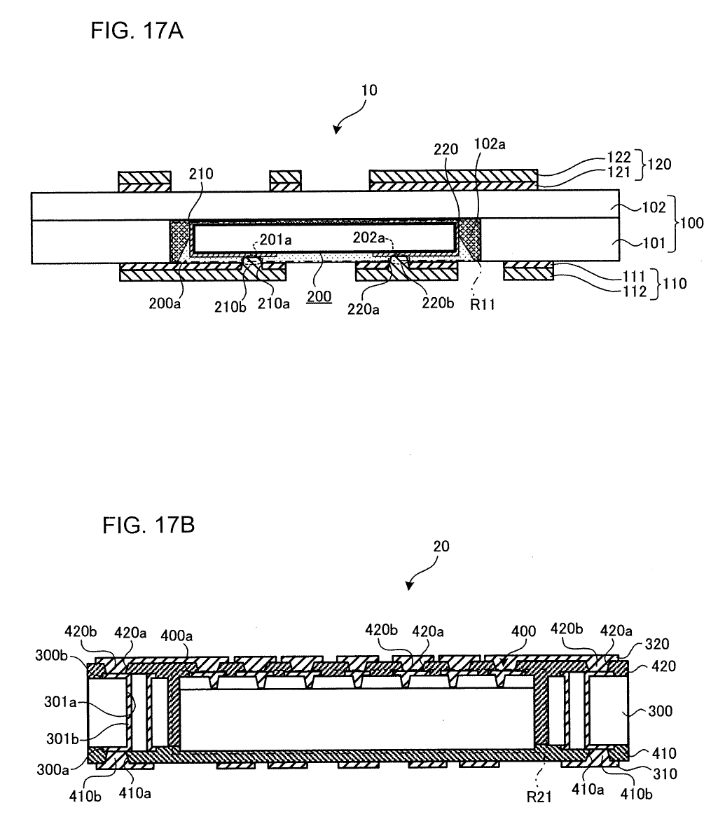

Via holes (201a, 202a, 410a, 420a) are not limited to forming conformal vias. As shown in FIGS. 17A, 17B, they may form filled vias which are filled with conductors (210b, 220b, 410b, 420b), for example.

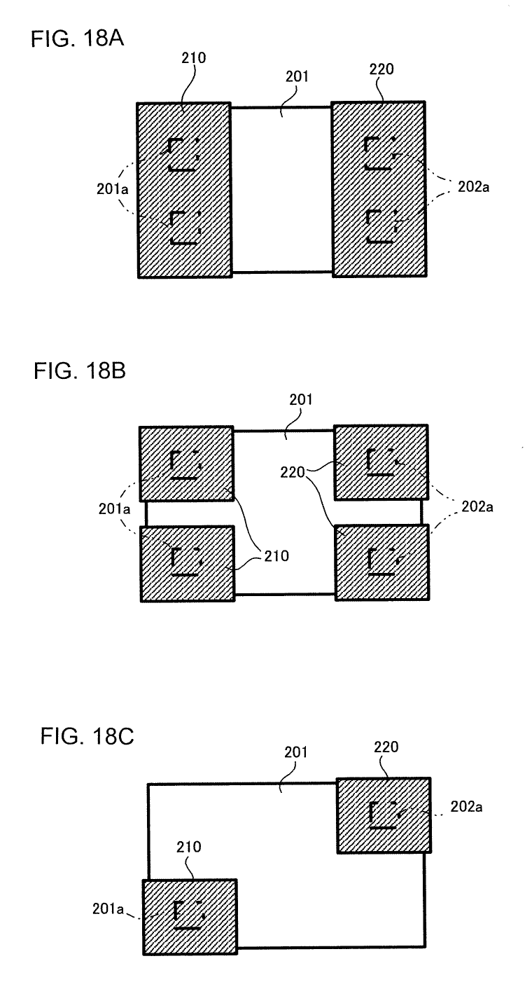

The number of electrodes of the electronic component or via holes along with their configurations may be modified to any number and configuration. For example, in the First Embodiment, via holes (201a, 202a) are formed in terminal electrodes (210, 220) to be one on one. However, as shown in FIG. 18A (a view corresponding to FIG. 3), for example, multiple (such as two) via holes (201a, 202a) may be formed in each of terminal electrodes (210, 220). In addition, as shown in FIG. 18B, for example, terminal electrodes (210, 220) along with via holes (201a, 202a) may be formed at the four corners of capacitor body (201). Also, as shown in FIG. 18C, for example, terminal electrodes (210, 220) along with via holes (201a, 202a) may be positioned diagonally on capacitor body (201). All the same apply to the Second Embodiment.

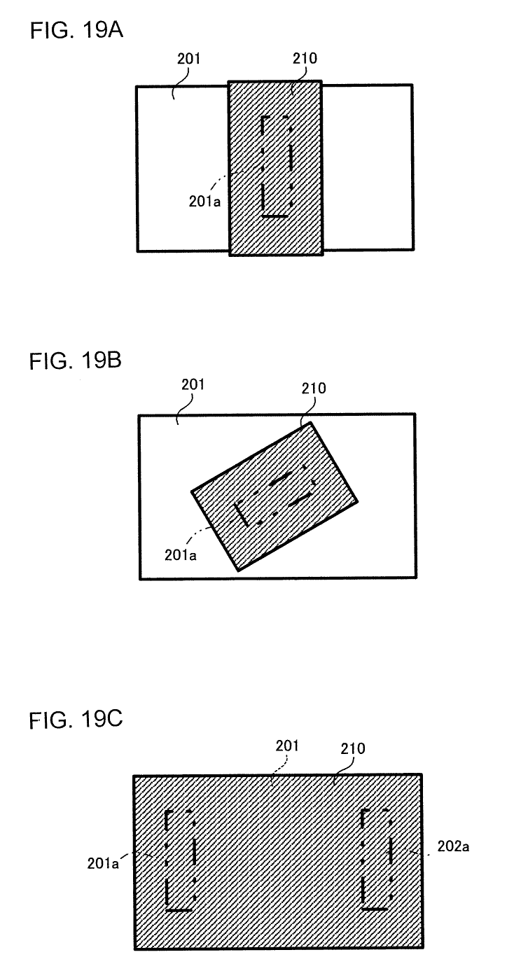

In the First Embodiment, via holes (201a, 202a) are connected to the end portions of electronic component (200). However, the present invention is not limited to such. For example, as shown in FIG. 19A, terminal electrode (210) and via hole (201a) may be arranged on the central portion of capacitor body (201). Alternatively, as shown in FIG. 19B, for example, terminal electrode (210) and via hole (201a) may be arranged obliquely to the sides of capacitor body (201). Also, as shown in FIG. 19C, for example, terminal electrode (210) may be arranged on the entire surface of capacitor body (201).

The configuration of terminal electrodes (210, 220) of electronic component (200) is not limited to a U-shape, but a pair of flat-plate electrodes may sandwich capacitor body (201).

Any type of electronic component may be used as electronic components (200, 400); for example, active components such as an IC chip or the like, and passive components such as a capacitor, resistor, coil or the like may be used.

In the above embodiments, the quality, size, the number of layers and so forth of each layer may be modified.

For example, to reduce the manufacturing costs, wiring board (10) or (20) with a built-in electronic component having a simple structure as shown previously in FIG. 1 or FIG. 13A may be preferred. However, the present invention is not limited to such. For example, to achieve high functionality, after the structure shown in FIG. 1 or FIG. 13A is complete, a lamination process may be further carried out to make it an even multilayer (for example, eight-layer) wiring board with a built-in electronic component.

The order of the steps in the above embodiments may be changed within a scope that will not deviate from the gist of the present invention. Also, unnecessary processes may be omitted according to usage requirements or the like.

So far, the embodiments of the present invention have been described. However, it should be understood that various modifications and combinations necessary for design convenience and other requirements will be included in the invention described in the “claims” and in the scope of the present invention corresponding to the specific examples described in the “embodiments of the present invention.”

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board comprising:
a substrate;
an electronic component having an electrode and arranged inside the substrate; and
a wiring layer formed over the substrate and connected to the electrode through a via hole,
wherein the electrode has a connection surface portion contacting the via hole, and the connection surface portion has a thickness which is made thinner than a thickness of the electrode surrounding the connection surface portion.

2. The wiring board according to claim 1, wherein the electronic component is a passive component.

3. The wiring board according to claim 2, wherein the electronic component is a chip capacitor.

4. The wiring board according to claim 1, wherein the electrode covers a side surface of the electronic component.

5. The wiring board according to claim 1, wherein a surface of the electrode is roughened.

6. The wiring board according to claim 1, wherein a resin is filled between the substrate and the electronic component.

7. The wiring board according to claim 1, wherein the wiring layer is formed on a surface of the substrate, and the electronic component is connected to the wiring layer through the via hole.

8. The wiring board according to claim 1, wherein the substrate contains a reinforcing material.

9. The wiring board according to claim 1, wherein a boundary portion of a bottom and wall surfaces of the via hole is rounded.

10. The wiring board according to claim 1, wherein the wiring layer comprises a metal foil and a plated metal film.

11. The wiring board according to claim 1, wherein a conductor is formed in the via hole, and the conductor and the via hole form a conformal via.

12. The wiring board according to claim 11, wherein a thickness of the conductor of the conformal via is made partially thinner.

13. A method for manufacturing a wiring board, comprising:
arranging inside a substrate an electronic component having an electrode;
making a part of the electrode thinner;
forming a via hole to be connected to the part of the electrode that was made thinner; and
forming a wiring layer to be connected to the electronic component through the via hole.

14. The method for manufacturing a wiring board according to claim 13, wherein a conductor is formed in the via hole, and a thickness of the conductor is partially made thinner.
